(19) United States
(12) Patent Application Publication
(10) Pub. No.: US 2012/0188727 A1
(43) Pub. Date: Jul. 26, 2012

(54) EMI Shielding in a Package Module

(75) Inventors: Nan-Chun LIN, Hukou Townshilp (TW); Ya-Yun Cheng, Hukou Township (TW); Jing-Hua Cheng, Hukou Townshilp (TW); Kuang-San Liu, Hukou Township (TW)

(73) Assignee: ADL Engineering Inc., Hukou Township (TW)

(21) Appl. No.: 13/011,937

(22) Filed: Jan. 24, 2011

(51) Int. Cl. H05K 7/00; H05K 13/04

(52) U.S. Cl. 361/728; 228/101; 228/155

(57) ABSTRACT

The present invention discloses a package module with EMI shielding and the method thereof. The package module has a substrate or a PCB with at least one ground pad. A variety of electronic components are mounted on the substrate. The dielectric layer overlays a selected area which covers some electronic components and ground pads. Openings are formed within the dielectric layer and above ground pads. The shielding layer with at least two metal layers covers the dielectric layer and is electrically coupled, via the openings, to the ground pad. In general, there is a protection layer to encapsulate the entire substrate. The package module of the present invention not only achieves the requirement of miniature packaging but also reduces EMI caused by high speed electronic devices.

### TECHNICAL FIELD

The present invention relates to an electronic package module, and more particularly to a package module with the function of EMI shielding and the characteristic of miniature packaging.

### BACKGROUND OF RELATED ART

Thanks to the rapid progress of semiconductor technology, the complexity and functionality of electronic products such as mobile phone, TV, notebook PC increases tremendously. More and more sophisticated and high speed semiconductor devices are packaged in a substrate or a printed circuit board (PCB). A high speed semiconductor device generates electromagnetic waves to interfere in the other electronic devices or is disturbed by electromagnetic waves emitted from the other high speed devices. The magnetic interference (EMI) adversely affects the operation of an electronic system and the problems caused by EMI are not new to manufacturers of electronic equipment.

One traditional approach to reduce EMI is to provide a discrete metal can over the molded semiconductor package. The metal can typically connects to a ground plane or a pad on a PCB to reduce EMI. However, the metal case undesirably increases the thickness of the package and that certainly can not meet the trend of miniature package. Besides, the formation of the metal can requires an extra process and additional material which significantly increases package cost. In another approach, conductive foam or rubber are applied over the molded package to absorb EMI. However, the conductive foam or rubber must be applied manually and require special material and an extra process which significantly increases package cost. Additionally, the conductive foam or rubber undesirably increases the thickness of the molded package as well. One advanced prior approach is to directly metalize a shielding surface and placing it in contact with the ground trace. Nevertheless, the shielding area covers the entire package and has less flexibility to change the shape and the area of shielding.

The present invention discloses an exemplary package module with EMI shielding and the method of making such module. A shielding layer is only required for a selected area. The selected area of the substrate has the electronic devices which will emit electromagnetic waves or are adversely susceptible to electromagnetic waves from the other electronic devices or systems. Therefore, the shape and area of the shielding layer can be designed flexibly and economically to save the material cost. In addition, because dedicated regions reserved for EMI shielding and/or larger ground space between each shielding area are no longer required, the packing density can be more compact.

### SUMMARY

The present invention discloses an EMI shielding in package module, the package module includes a substrate with at least one ground pad, a variety of electronic components mounted on the substrate, a dielectric layer covering a selected area, a plurality of openings formed within the dielectric and above the ground pad, a shielding layer covering the dielectric layer, a joint layer overlaying the shielding layer, and a protection layer covering over the entire substrate.

The selected area covers a portion of the substrate. The substrate under the selected area is mounted with the electronic components emitting electromagnetic waves or being adversely susceptible to electromagnetic waves. Electrically coupled to the ground pad via the openings, the shielding layer, which can reduce EMI, includes at least two metal layers to improve adhesion between the shielding layer and the dielectric layer.

The joint layer is deposited over the shielding layer to enhance adhesion between the shielding layer and the protection layer. However, the joint layer can be saved provided that there are no adhesion issues between the shielding layer and the protection layer. Being a blanket layer encapsulating the entire substrate, the protection layer is an insulating material which can prevent the package module from ambient contamination and moisture.

In one embodiment, the substrate includes PCB, Semiconductor, Ceramic, Glass, or any combination thereof. To electrically isolate the ground pads and the electronic components from the shielding layer, the dielectric layer is an insulator such as SiO₂, Si₃N₄, or any chemical composition consists of Silicon (Si), Nitrogen (N), and Oxygen (O).

The present invention discloses a method of forming the package module with EMI shielding, the method includes providing a substrate with at lest one ground pad; disposing a variety of electronic components on the substrate; executing a reflow process to couple the electronic components with the substrate; depositing a dielectric layer on a selected area which covers a portion of the substrate containing some the electronic components and the ground pad; forming a plurality of openings within the dielectric layer over the ground pad; forming a shielding layer which covers the dielectric layer and is electrically coupled, via the openings, to the ground pad; and forming a protection layer over the entire substrate. In one embodiment, a joint layer is formed over the shielding layer before the formation of the protection layer.

Some exemplary of techniques to form a variety of layers are described below. In one embodiment, the technique of forming the ground pad includes sputtering, printing, E-plating, Physical Vapor Deposition (PVD), Chemical Vapor Deposition (CVD), or any combination thereof. The technique of forming the dielectric layer includes, sputtering, CVD, printing, or any combination thereof. The technique of forming the shielding layer includes sputtering, printing, E-plating, PVD, CVD, or any combination thereof. The technique of forming the joint layer includes sputtering, printing, CVD or any combination thereof. The technique of forming the protection layer includes injection, printing, molding process, or any combination thereof

### BRIEF DESCRIPTION OF THE DRAWINGS

The above objects, and other features and advantages of the present invention will become more apparent after reading the following detailed description when taken in conjunction with the drawings, in which:

FIG. 1 illustrates one exemplary package module of the present invention.

FIG. 2 illustrates the shielding area covering only a portion of the substrate.

FIG. 3(a) illustrates a substrate or PCB with ground pads being provide d first.

FIG. 3(b) illustrates a variety of electronic components mounted on the substrate and a dielectric layer deposited over the shielding area.

FIG. 3(c) illustrates openings formed within the dielectric layer above the ground pad and a shielding layer deposited over the dielectric layer and the openings.

FIG. 4(a) illustrates a protection layer blanket covering the entire substrate or PCB.

FIG. 4(b) illustrates a joint layer deposited over the shielding layer before the formation of the protection layer.

### DETAILED DESCRIPTION

Some of the embodiment of the present invention will be described in detail by using the following embodiments and it will be recognized that those descriptions and examples of embodiments are used to illustrate but not to limit the claims of the present invention. Hence, other than the embodiments described in the following, the present invention may be applied to the other substantially equivalent embodiments.

An EMI shielding in a package module with a low profile shielding layer and the method thereof are described in detail below. The package module of the present invention effectively reduces the electromagnetic waves emitting from a high speed electronic device or coming from the other electronic devices. The electromagnetic interference (EMI) between electronic devices or systems affects the normal operation of electronic product.

Owing to the low profile shielding layer, the package module of the present invention is not bulky and that meets the requirement of miniature packaging in current application. Besides, the area and shape of the shielding layer is not fixed and can be designed flexibly. Therefore, the ground pad space between each shielding area can be reduced so that the material of dielectric layer and shielding layer can be saved with a large amount.

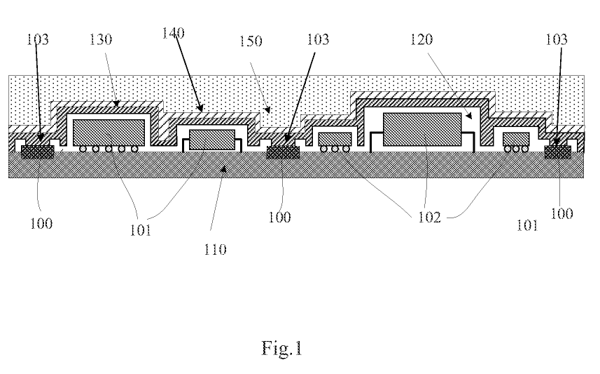

In one embodiment, as shown in FIG. 1, an exemplary package structure of the present invention is disclosed. A substrate 110 such as printed circuit board (PCB), semiconductor substrate, ceramic, glass or any combination thereof acts as a base to support a variety of active electronic components 101 and passive components 102 thereon. The material of substrate 110 is not limited by the above-mentioned materials because the main function of the substrate 110 is to be a base.

A substrate 110 with electrical circuits, a plurality of contact pads, ground planes or ground pads 100 are mounted with a variety of active electronic components 101 and passive components 102. Afterward, a dielectric layer 120 is deposited thereon to electrically isolate the electrical circuits and the electronic components on the substrate 110 from the shielding layer 130. In general, SiO₂, Si₃N₄, or the chemical composition of SiₓN_{y} is used as the dielectric layer 120. However, the material of the dielectric layer 120 of the present invention is not limited by the aforementioned chemical compositions as long as the material of the dielectric layer 120 is an insulator.

A plurality of openings above ground pads 100 are formed within the dielectric layer 120 so that the shielding layer 130 electrically couples with the ground pads 100. Containing at least two metal layers, the shielding layer 130 is deposited over the dielectric layer 120 and fills the openings 103 to reduce EMI. In one embodiment, the shielding layer 130 is a multi-layer structure of Cu/Ti or Ti/Cu/Ti for the purpose of EMI shielding and adhesion improvement between layers.

A joint layer 140 is deposited over the shielding layer 130 to enhance the adhesion of the following layer, protection layer 150. Used for encapsulating the package module and preventing it from moisture and contamination, the protection layer 150 is a material known as molding compounds which generally consists essentially of epoxy resins, phenolic hardeners, silicas, catalysts, pigments, and mold release agents. In one embodiment, the joint layer 140 can be skipped provided the skip will not induce adhesion problem of the protection layer 150.

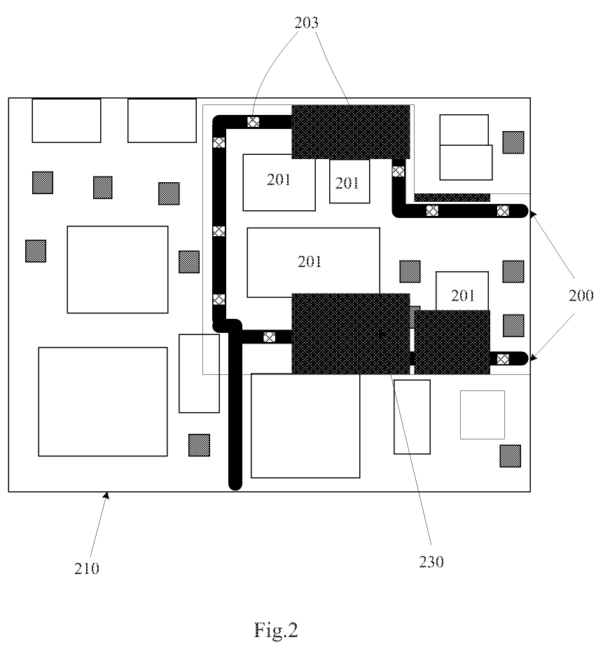

In one embodiment, the shape and the area of shielding layer 130 can be designed flexibly for a specific region instead of the entire region of the substrate 110. As shown in FIG. 2, provided that, in the whole substrate 210, only the active electronic components 201 will emit electromagnetic waves or are adversely susceptible to electromagnetic, a shielding layer 230 just needs to cover those components 201, and consequently the placement of electronic components can be more flexible and compact because a specific large area designed for EMI shielding is no longer required. Owing to electrically coupled with the ground pad 200 through a plurality of openings 203, the shielding layer 230 is able to absorb the electromagnetic waves.

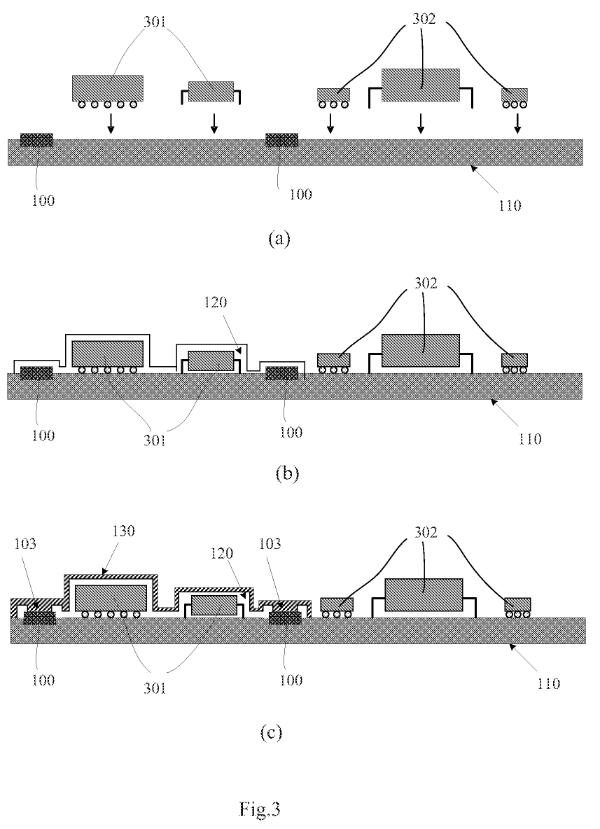

The process of fabricating a package module with a selected EMI shielding area is described below. As shown in FIG. 3(a), first of all, a substrate 110 containing electrical circuits, connection pads, ground pads 100 are provided and then electronic components 301 302 are mounted thereon by a reflow process. The electrical circuits, connection pads, ground pads 100 are formed by sputtering, printing, electroplating (E-plating), Physical Vapor Deposition (PVD), Chemical Vapor Deposition (CVD) or any combination thereof. Supposing the components 301 are selected to be covered by an EMI shielding layer, a dielectric layer 120, by using sputtering, CVD, printing, or any combination thereof, is deposited over the components 301 and the adjacent ground pads 100, as shown in FIG. 3(b). Defining the EMI shielding area, the dielectric layer 120 can be any shape as long as it covers the components needing EMI shielding.

A plurality of openings 103 are formed over ground pads 100 by executing the process of coating photo-resist, lithography and etching. In another embodiment, openings 103 are formed by laser cut. Following the dielectric layer 120, as shown in FIG. 3(c), a shielding layer 130 containing at least two metal layers is formed thereon by using sputtering, printing, E-plating, PVD, CVD, or any combination thereof. To have developed to this point, a package module with EMI shielding is accomplished.

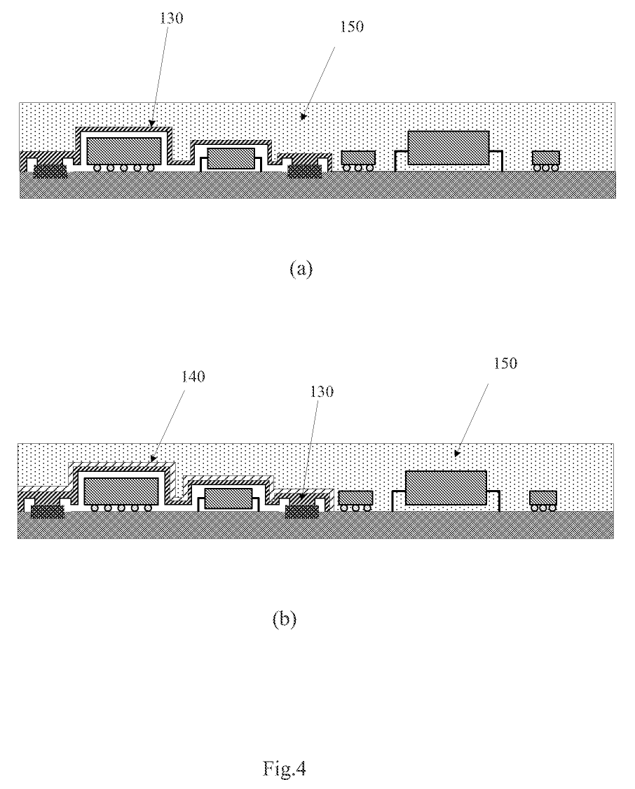

In one embodiment, the package module with EMI shielding layer is encapsulated by a molding compound as a protection layer to prevent the inner devices of the package module from contamination and/or moisture from ambiance. As shown in FIG. 4(a), a protection layer 150 is formed over the entire package module by employing injection, printing, molding process, or any combination thereof. In another embodiment, as shown in FIG. 4(b), in order to enhance adhesion between the protection layer 150 and the shielding layer 130, an joint layer 140 is first formed over the shielding layer 140 by employing injection or printing process, and thereupon the protection layer 150 is molded.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. An EMI shielding in package module comprising:
a substrate with at least one ground pad;
a variety of electronic components mounted on said substrate;
a dielectric layer overlaying a selected area which covers a portion of said substrate containing some said electronic components and said ground pad.
a plurality of openings formed within said dielectric layer and above said ground pad, and
a shielding layer covering said dielectric layer and being electrically coupled, via said openings, to said ground pad;

2. The EMI shielding in package module according to claim 1, further comprises a joint layer formed on said shielding layer.

3. The EMI shielding in package module according to claim 1, further comprises a protection layer covering over entire said substrate.

4. The EMI shielding in package module according to claim 2, further comprises a protection layer covering over entire said substrate, wherein said joint layer enhances adhesion between said shielding layer and said protection layer.

5. The EMI shielding in package module according to claim 1, wherein said substrate includes PCB, Semiconductor, Ceramic, Glass, or any combination thereof

6. The EMI shielding in package module according to claim 1, wherein said dielectric layer includes an insulating material to electrically isolate said ground pad and said electronic components from said shielding layer.

7. The EMI shielding in package module according to claim 1, wherein said selected area is a specific region of said substrate in which are situated said electronic components emitting electromagnetic waves or being susceptible to electromagnetic waves.

8. The EMI shielding in a package module according to claim 1, wherein said shielding layer reduces EMI and includes at least two metal layers to improve adhesion of said shielding layer.

9. The EMI shielding in package module according to claim 3, wherein said protection layer includes an insulating material to resist moisture or contamination from ambiance.

10. The EMI shielding in package module according to claim 4, wherein said protection layer includes an insulating material to resist moisture or contamination from ambiance.

11. A method of forming EMI shielding in package module according to claim 1 comprises:
providing a substrate with at lest one ground pad;
placing a variety of electronic components on said substrate;
executing a reflow process to couple said electronic components with said substrate;
depositing a dielectric layer on a selected area which covers a portion of said substrate containing some said electronic components and said ground pad. forming a plurality of openings within said dielectric layer and over said ground pad; and
forming a shielding layer which covers said dielectric layer and is electrically coupled, via said openings, to said ground pad;

12. The method of forming EMI shielding in package module according to claim 11, further comprises forming a joint layer on said shielding layer.

13. The method of forming EMI shielding in package module according to claim 11, further comprises forming a protection layer over entire said substrate.

14. The method of forming EMI shielding in package module according to claim 12, further comprises forming a protection layer covering over entire said substrate.

15. The method of forming EMI shielding in package module according to claim 11, wherein techniques of forming said ground pad include sputtering, printing, E-plating, PVD, or CVD.

16. The method of forming EMI shielding in package module according to claim 11, wherein techniques of forming said dielectric layer include, sputtering, CVD, or printing.

17. The method of forming the EMI shielding in package module according to claim 11, wherein techniques of forming said shielding layer include sputtering, printing, E-plating, PVD, or CVD.

18. The method of forming EMI shielding in package module according to claim 12, wherein techniques of forming said joint layer include sputtering, printing, or CVD.

19. The method of forming EMI shielding in package module according to claim 13, wherein techniques of forming said protection layer include injection, printing, or molding process.

20. The method of forming EMI shielding in package module according to claim 14, wherein techniques of forming said protection layer include injection, printing, or molding process.
